(19) United States
(12) Patent Application Publication
(10) Pub. No.: US 2010/0129648 A1
(43) Pub. Date: May 27, 2010

(54) ELECTRONIC PACKAGING AND HEAT SINK BONDING ENHANCEMENTS, METHODS OF PRODUCTION AND USES THEREOF

(76) Inventors: Jun Xu, Liberty Lake, WA (US); Andrew D. Delano, Spokane Valley, WA (US)

Correspondence Address: HONEYWELL INTERNATIONAL INC.;PATENT SERVICES, 101 COLUMBIA ROAD, P O BOX 2245, MORRISTOWN, NJ, 07962-2245, US

(21) Appl. No.: 12/323,913

(22) Filed: Nov. 26, 2008

(51) Int. Cl. B32B 27/32; B32B 9/04; H05K 3/10

(52) U.S. Cl. 428/339; 428/451; 428/484.1; 29/846

(57) ABSTRACT

Electronic components described herein include a heat generating component surface; a heat sink having a top surface and a bottom surface; and a thermal interface material comprising a phase change material, wherein the heat generating component surface is coupled to the bottom surface of the heat sink by the thermal interface material. Methods of forming an electronic component include: a) providing a heat-generating component surface; b) providing at least one thermal interface material; c) providing a heat sink component having a top surface and a bottom surface; d) depositing the at least one thermal interface material onto at least part of at least one of the surfaces of the heat sink component, and e) coupling the surface of the heat sink component with the thermal interface material layer with the heat generating component surface to produce the electronic component.

### FIELD OF THE SUBJECT MATTER

The field of the subject matter is bonding enhancement for heat sinks and related components utilized in electronic components, semiconductor components and other related layered materials applications.

### BACKGROUND

Electronic components are used in ever increasing numbers in consumer and commercial electronic products. Examples of some of these consumer and commercial products are televisions, flat panel displays, personal computers, gaming systems, Internet servers, cell phones, pagers, palm-type organizers, portable radios, car stereos, or remote controls. As the demand for these consumer and commercial electronics increases, there is also a demand for those same products to become smaller, more functional, and more portable for consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging. Products and components also need to be prepackaged, such that the product and/or component can perform several related or unrelated functions and tasks. Examples of some of these “total solution” components and products comprise layered materials, mother boards, cellular and wireless phones and telecommunications devices and other components and products, such as those found in US patent and PCT Application Ser. Nos. 60/396,294 filed Jul. 15, 2002, 60/294,433 filed May 30, 2001, 10/519,337 filed Dec. 22, 2004, 10/551,305 filed Sep. 28, 2005, 10/465,968 filed Jun. 26, 2003 and PCT/US02/17331 filed May 30, 2002, which are all commonly owned and incorporated herein in their entirety.

Components, therefore, are being broken down and investigated to determine if there are better building materials and methods that will allow them to be scaled down and/or combined to accommodate the demands for smaller electronic components. In layered components, one goal appears to be decreasing the number of the layers while at the same time increasing the functionality and durability of the remaining layers and surface/support materials. This task can be difficult, however, given that several of the layers and components of the layers should generally be present in order to operate the device.

Also, as electronic devices become smaller and operate at higher speeds, energy emitted in the form of heat increases dramatically with heat flux often exceeding 100 W/cm². A popular practice in the industry is to use thermal grease, or grease-like materials, alone or on a carrier in such devices to transfer the excess heat dissipated across physical interfaces. Most common types of thermal interface materials are thermal greases, phase change materials, and elastomer tapes. Thermal greases or phase change materials have lower thermal resistance than elastomer tape because of the ability to be spread in very thin layers and provide intimate contact between adjacent surfaces. Typical thermal impedance values range between 0.05-1.6° C.-cm²/W. However, a serious drawback of thermal grease is that thermal performance deteriorates significantly after thermal cycling, such as from −65° C. to 150° C., or after power cycling when used in VLSI chips. The most common thermal greases use silicone oils as the carrier. It has also been found that the performance of these materials deteriorates when large deviations from surface planarity causes gaps to form between the mating surfaces in the electronic devices or when large gaps between mating surfaces are present for other reasons, such as manufacturing tolerances, etc. When the heat transferability of these materials breaks down, the performance of the electronic device in which they are used is adversely affected.

In some recently developed packaging for electronics systems, including large servers, work stations and personal computers (PCs), heat sinks are directly applied on the top of a die without utilizing a heat spreader, which is referred to as a “bare die” technique. A layer of thermal interface material (TIM) is usually applied between the die and the heat sink; however, because of the typically small foot print (area) of the die and simplicity of the heat sink locking mechanism, the bonding between the heat sink bottom surface and the die is very weak and vulnerable to thermal stress, PCB board warping, and force imbalance of the locking mechanism during production, installation and operation.

Thus, there is a continuing need to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) produce materials and layers that are more compatible with other layers, surfaces and support materials at the interface of those materials; d) develop reliable methods of producing desired thermal interconnect materials, thermal interface materials and layered materials and components/products comprising contemplated thermal interface and layered materials; e) develop materials that possess a high thermal conductivity and a high mechanical compliance; f) effectively reduce the number of production steps necessary for a package assembly, which in turn results in a lower cost of ownership over other conventional layered materials and processes; and g) enhancing bonding of the die and heat sink during commercialization of the “bare die” technique and mass production of these components.

### SUMMARY

Electronic components described herein include a heat generating component surface; a heat sink having a top surface and a bottom surface; and a thermal interface material comprising a phase change material, wherein the heat generating component surface is coupled to the bottom surface of the heat sink by the thermal interface material.

Methods of forming an electronic component include: a) providing a heat-generating component surface; b) providing at least one thermal interface material; c) providing a heat sink component having a top surface and a bottom surface; d) depositing the at least one thermal interface material onto at least part of at least one of the surfaces of the heat sink component, and e) coupling the surface of the heat sink component with the thermal interface material layer with the heat generating component surface to produce the electronic component.

### BRIEF DESCRIPTION OF THE FIGURES

FIG. 1 shows a contemplated embodiment of a die and heat sink combined component comprising a suitable thermal interface material prior to heating.

FIG. 2 shows a contemplated embodiment of a die and heat sink combined component comprising a suitable thermal interface material after heating.

FIG. 3 shows a summary of these experiments plotting application thickness in millimeters versus breaking force (kgf).

### DETAILED DESCRIPTION

A suitable interface material or component should conform to the mating surfaces (deforms to fill surface contours and “wets” the surface), possess a low bulk thermal resistance and possess a low contact resistance. Bulk thermal resistance can be expressed as a function of the material's or component's thickness, thermal conductivity and area. Contact resistance is a measure of how well a material or component is able to transfer heat across the interface which is largely determined by the amount and type of contact between the two materials. One of the goals of the materials and methods described herein is to minimize contact resistance without a significant loss of performance from the materials. The thermal resistance of an interface material or component can be shown as follows:

Θ interface=t/k+2Θ_{contact} Equation 1
where
   Θ is the thermal resistance,
   t is the material thickness,
   k is the thermal conductivity of the material

The term “t/k” represents the thermal resistance of the bulk material and “2Θ_{contact}” represents the thermal contact resistance at the two surfaces. A suitable interface material or component should have a low bulk resistance and a low contact resistance, i.e. at the mating surface.

Many electronic and semiconductor applications require that the interface material or component accommodate deviations from surface flatness resulting from manufacturing and/or warpage of components because of coefficient of thermal expansion (CTE) mismatches.

A material with a low value for k, such as thermal grease, performs well if the interface is thin, i.e. the “t” value is low. If the interface thickness increases by as little as 0.002 inches, the thermal performance can drop dramatically. Also, for such applications, differences in GTE between the mating components cause the gap to expand and contract due to warpage with each temperature or power cycle. This variation of the interface thickness can cause pumping of fluid interface materials (such as grease) away from the interface.

Interfaces with a larger area are more prone to deviations from surface planarity as manufactured. To optimize thermal performance, the interface material should be able to conform to non-planar surfaces and thereby achieve lower contact resistance. As used herein, the term “interface” means a couple or bond that forms the common boundary between two parts of matter or space, such as between two molecules, two backbones, a backbone and a network, two networks, etc. An interface may comprise a physical attachment of two parts of matter or components or a physical attraction between two parts of matter or components, including bond forces such as covalent and ionic bonding, Van der Waals, diffusion bonding, hydrogen bonding and non-bond forces such as electrostatic, coulombic, and/or magnetic attraction. Contemplated interfaces include those interfaces that are formed with bond forces, such as covalent and metallic bonds; however, it should be understood that any suitable adhesive attraction or attachment between the two parts of matter or components is preferred.

Optimal interface materials and/or components possess a high thermal conductivity and a high mechanical compliance, e.g. will yield, elastically or plastically at the local level when force is applied. High thermal conductivity reduces the first term of Equation 1 while high mechanical compliance reduces the second term. The layered interface materials and the individual components of the layered interface materials described herein accomplish these goals. When properly produced, the thermal interface component described herein will span the distance between the mating surfaces, e.g. that of the heat spreader material and the silicon die component, thereby allowing a continuous high conductivity path from one surface to the other surface.

As mentioned earlier, several goals of thermal interface materials, layered interface materials and individual components described herein are to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) produce materials and layers that are more compatible with other layers, surfaces and support materials at the interface of those materials; d) develop reliable methods of producing desired thermal interconnect materials, thermal interface materials and layered materials and components/products comprising contemplated thermal interface and layered materials; e) develop materials that possess a high thermal conductivity and a high mechanical compliance; f) effectively reduce the number of production steps necessary for a package assembly, which in turn results in a lower cost of ownership over other conventional layered materials and processes; and g) enhancing bonding of the die and heat sink during commercialization of the “tare die” technique and mass production of these components.

Electronic components described herein include a heat generating component surface, which may be an electronic component surface; a heat sink having a top surface and a bottom surface; and a thermal interface material comprising a phase change material, wherein the heat generating component surface is coupled to the bottom surface of the heat sink by and through the thermal interface material.

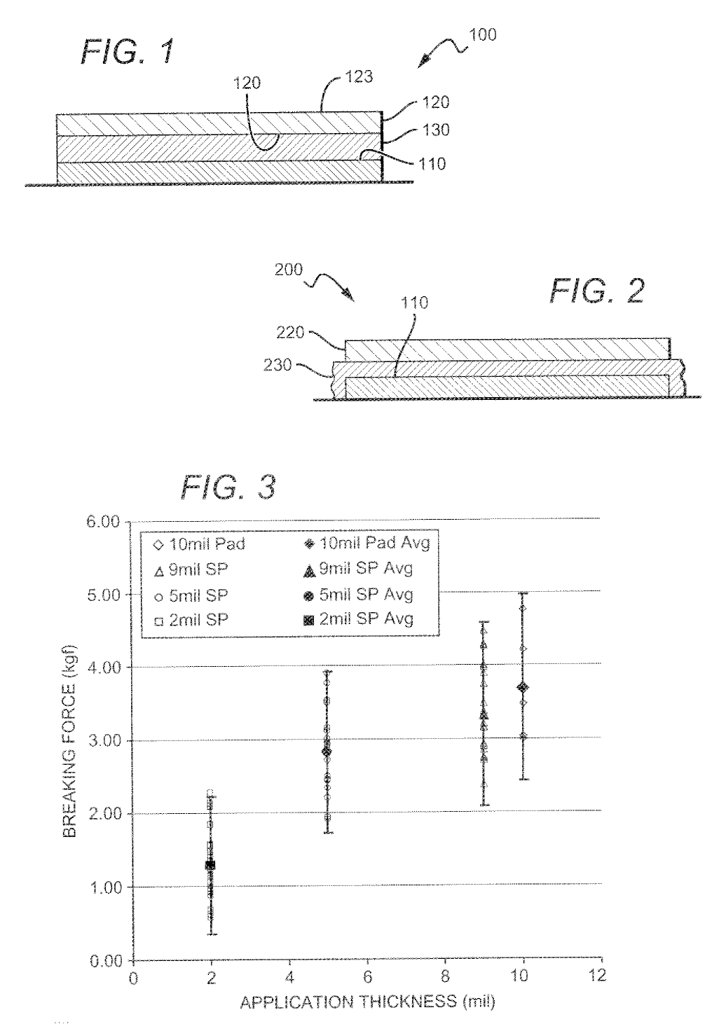

FIG. 1 shows a contemplated electronic component 100 comprising heat generating component surface, such as an electronic component surface 110, a heat sink 120 having a top surface 123 and a bottom surface 126, and a thermal interface material 130, wherein the thermal interface material 130 comprises a phase change material (not individually shown). FIG. 2 shows the same electronic component 200 comprising a heat generating component surface 210 and a heat sink 220 after heating, wherein the thermal interface material 230 has “melted” around the component 200.

Ideally, contemplated components comprise a suite of thermal interface materials that exhibit low thermal resistance for a wide variety of interface conditions and demands. Thermal interface materials contemplated herein can be used to attach the heat generating electronic devices (e.g. the computer chip) to the heat dissipating structures (e.g. heat spreaders, heat sinks). The performance of the thermal interface materials is one of the most important factors in ensuring adequate and effective heat transfer in these devices.

Thermal interface materials comprise at least one phase change material and may additionally comprise at least one high conductivity filler and/or at least one solder material in some embodiments. As used herein, “high conductivity filler” means that the filler comprises a thermal conductivity of greater than about 20 and in some embodiments, at least about 40 W/m° C. Optimally, it is desirable to have a filler component of not less than about 80 W/m° C. thermal conductivity. Methods of forming these thermal interface materials comprise providing each of the at least one matrix material, at least one high conductivity filler and at least one solder material, blending the components and optionally curing the components pre- or post-application of the thermal interface material to the surface, substrate or component.

Phase change materials are useful in thermal interface component applications because they are solid at room temperature and can easily be pre-applied to thermal management components. At operation temperatures above the phase change temperature, the material changes phases to become liquid or semi-liquid and behaves like a thermal grease. The phase change temperature is the melting temperature, where the material transforms from a soft solid at low temperatures to a viscous liquid at higher temperatures.

The at least one phase change material may comprise any suitable phase change material. Phase-change materials that are contemplated herein comprise waxes, polymer waxes or mixtures thereof, such as paraffin wax. Paraffin waxes are a mixture of solid hydrocarbons having the general formula CₙH₂ₙ₊₂ and having melting points in the range of about 20° C. to 145° C. Examples of some contemplated melting points are about 45° C. and 60° C. Thermal interface components that have melting points in this range are PCM45 and PCM60HD—both manufactured by Honeywell International Inc. Polymer waxes are typically polyethylene waxes, polypropylene waxes, and have a range of melting points from about 40° C. to 160° C.

PCM45 comprises a thermal conductivity of about 3.0 W/m-K, a thermal resistance of about 0.25° C.-cm²/W at 0.05 mm thickness, may be applied at a thickness of about 0.010 inches (0.254 mm) and comprises a soft material above the phase change temperature of approximately 45° C., flowing easily under an applied pressure of about 5 to 30 psi. Typical characteristics of PCM45 are a) a super high packaging density—over 80 weight %, b) a conductive filler, c) extremely low thermal resistance, and as mentioned earlier d) about a 45° C. phase change temperature. PCM60HD comprises a thermal conductivity of about 5.0 W/mK, a thermal resistance of about 0.17° C.-cm²/W, is typically applied at a thickness of about 0.0015 inches (0.04 mm) and comprises a soft material, flowing easily under an applied pressure of about 5 to 30 psi. Typical characteristics of PCM60HD are a) a super high packaging density—over 80 weight %, b) a conductive filler, c) extremely low thermal resistance, and as mentioned earlier d) about a 60° C. phase change temperature.

TM200 (a thermal interface component not comprising a phase change material and manufactured by Honeywell International Inc.) comprises a thermal conductivity of about 3.0 W/mK, a thermal resistance of below 0.20° C.-cm²/W, is typically applied at a thickness of about 0.002 inches (0.05 mm) and comprises a paste that can be thermally cured to a soft gel. Typical characteristics of TM200 are a) a super high packaging density over 80 weight %, b) a conductive filler, c) extremely low thermal resistance, d) about a 125° C. curing temperature, and e) dispensable silicone-based thermal gel.

PCM45F comprises a thermal conductivity of about 2.35 W/mK, a thermal resistance of about 0.20° C.-cm²/W, is typically applied at a thickness of about 0.050 mm [application thickness is generally 0.2-0.25 mm (8-10 mil), but it normally compresses to 0.05 mm (2 mil)] and comprises a soft material, flowing easily under an applied pressure of about 5 to 40 psi. Typical characteristics of PCM45F are a) a super high packaging density—over 80 weight %, b) a conductive filler, c) extremely low thermal resistance, and as mentioned earlier d) about a 45° C. phase change temperature. PCM45FSP is similar to PCM45F, except that it is screen printable or stencilable. Both PCM45F and PCM45FSP possess very good wetting to most electronic materials, including silicon, silicon oxide, PCB board material, ceramics, aluminum, copper, anodized surfaces, painted surfaces or a combination thereof. These materials also have good tensile and shear strengths before and after phase change compared to most thermal greases and related compounds.

In some embodiments, there may be at least one high conductivity filler component dispersed in the thermal interface. Suitable filler materials include silver, copper, aluminum, and alloys thereof; boron nitride, aluminum spheres, aluminum nitride, silver coated copper, silver coated aluminum, carbon fibers, and carbon fibers coated with metals, metal alloys, conductive polymers or other composite materials. Combinations of boron nitride and silver or boron nitride and silver/copper also provide enhanced thermal conductivity. Boron nitride in amounts of at least 20 wt % and silver in amounts of at least about 60 wt % are particularly useful. These materials may also comprise metal flakes or sintered metal flakes. As mentioned earlier, it is contemplated that filler components with a thermal conductivity of greater than about 20 and in some embodiments, at least about 40 W/m° C. can be used. Optimally, it is desired to have a filler component of not less than about 80 W/m° C. thermal conductivity. In some embodiments, the filler components comprise large silver powders (20 microns) from TECHNIC, small silver powders (3 microns) from METALOR, or a combination thereof.

In some embodiments, the at least one high conductivity filler component comprises at least some components having a diameter less than about 40 micrometers. In other embodiments, the diameter of at least some of those components is less than about 30 micrometers. In yet other embodiments, the diameter of at least some of those components is less than about 20 micrometers. It should be understood that the phrase “at least some of those components” or “at least some components” means that in the group of at least one high conductivity filler component, some of the components have the stated diameter, but other components may have other diameters. It may also be advantageous to have the average component diameter to be less than about 40 micrometers—meaning that some of the component diameters may be greater than 40 micrometers and others less than about 40 micrometers, but the average component diameter is less than about 40 micrometers.

Contemplated high conductivity filler components also may comprise reinforcement materials, such as screens, mesh, foam, cloth or combinations thereof. Contemplated mesh may comprise copper, silver, gold, indium, tin, aluminum, iron, screen, foam, cloth, graphite, carbon fibers or combinations thereof. Contemplated high conductivity filler components also comprise silver, copper, aluminum or alloys thereof, boron nitride, aluminum spheres, aluminum nitride, silver-coated copper, silver-coated aluminum, carbon fibers, carbon fibers coated with metals, carbon nanotubes, carbon nanofibers, metal alloys, conductive polymers or other composite materials, metal-coated boron nitride, metal-coated ceramics, diamond, metal-coated diamond, graphite, metal-coated graphite and combinations thereof.

Thermal reinforcements, which are considered to be high conductivity filler components, comprise highly conductive metals, ceramics, composites, or carbon materials, such as low CTE materials or shape memory alloys. Metal or other highly conductive screen, mesh, cloth, or foam are used to enhance thermal conductivity, tailor CTE, adjust BLT, and/or modify modulus and thermal fatigue life of the TIM. Examples include Cu, Al and Ti foam (e.g. 0.025 to 1.5 mm pore size with 30-90 vol % porosity from Mitsubishi), Cu or Ag mesh or screen (e.g. wire diameter 0.05-0.15 mm, 100-145 mesh from McNichols Co), or carbon/graphite cloth (e.g. 5.7 oz/yd² plain weave, 0.010″ thick, from US Composites).

A suitable interface material can also be produced/prepared, that comprises a solder material. The solder material may comprise any suitable solder material or metal, such as indium, silver, copper, aluminum, tin, bismuth, lead, gallium and alloys thereof, but it is preferred that the solder material comprise indium or indium-based alloys.

Solder materials that are dispersed in the resin mixture are contemplated to be any suitable solder material for the desired application. Preferred solder materials are indium tin (in Sn) alloys, indium silver (InAg) alloys, indium-bismuth (InBi) alloys, tin indium bismuth (SnInBi) indium tin silver zinc (InSnAgZn), indium-based alloys, tin silver copper alloys (SnAgCu), tin bismuth and alloys (SnBi), and gallium-based compounds and alloys. Especially preferred solder materials are those materials that comprise indium. The solder may or may not be doped with additional elements to promote wetting to the heat spreader or die backside surfaces.

As used herein, the term “metal” means those elements in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include indium, silver, copper, aluminum, tin, bismuth, lead, gallium and alloys thereof, silver coated copper, and silver coated aluminum. The term “metal” also includes alloys, metal/metal composites, metal ceramic composites, metal polymer composites, as well as other metal composites. As used herein, the term “compound” means a substance with constant composition that can be broken down into elements by chemical processes. As used herein, the phrase “metal-based” refers to any coating, film, composition or compound that comprises at least one metal.

In some embodiments, the at least one solder component comprises at least some components having a diameter less than about 40 micrometers. In other embodiments, the diameter of at least some of those components is less than about 30 micrometers. In yet other embodiments, the diameter of at least some of those components is less than about 20 micrometers. It may also be advantageous to have the average component diameter to be less than about 40 micrometers—meaning that some of the component diameters may be greater than 40 micrometers and others less than about 40 micrometers, but the average component diameter is less than about 40 micrometers.

The solder-based interface materials, as described herein, have several advantages directly related to use and component engineering, such as: a) high bulk thermal conductivity, b) metallic bonds may be formed at the joining surfaces, lowering contact resistance c) the interface solder material can be easily incorporated into micro components, components used for satellites, and small electronic components.

Vapor grown carbon fibers and other fillers, such as substantially spherical filler particles may be incorporated. Additionally, substantially spherical shapes or the like will also provide some control of the thickness during compaction. Dispersion of filler particles can be facilitated by the addition of functional organometallic coupling agents or wetting agents, such as organosilane, organotitanate, organozirconium, etc. Typical particle sizes useful for fillers in the resin material may be in the range of about 1-20 μm with a maximum of about 100 μm.

These compounds may comprise at least some of the following: at least one silicone compound in 1 to 20 weight percent, organotitanate in 0-10 weight percent, at least one solder material in 5 to 95 weight percent, at least one high conductivity filler in 0-90 weight percent. These compounds may include one or more of the optional additions, e.g., wetability enhancer. The amounts of such additions may vary but, generally, they may be usefully present in the following approximate amounts (in wt. %): filler up to 95% of total (filler plus resins); wetability enhancer 0.1 to 5% (of total), and adhesion promoters 0.01 to 1% (of total). It should be noted that the addition of at least about 0.5% carbon fiber significantly increases thermal conductivity. These compositions are described in U.S. Pat. No. 6,706,219. U.S. application Ser. No. 10/775,989 filed on Feb. 9, 2004 and PCT Serial No.: PCT/US02/14613, which are all commonly owned and incorporated herein in their entirety by reference.

Contemplated thermal interface materials have several advantages directly related to use and component engineering, such as: a) the ability to be layered in thicknesses of at least about 0.127 mm or 5 mils prior to phase change of the phase change material, and in some cases at least about 0.178 mm or 7 mils prior to phase change of the phase change material and at least about 0.254 mm or 10 mils prior to phase change of the phase change material, which is a thickness that grease or related compound cannot achieve; b) providing a good cushion layer to protect the electronic component surface from the heat sink's unbalanced mechanical load or contact (if any) during the production or installation of the electronic component; c) the ability to melt and achieve a very thin bond line thickness once the electronic system is turned on; d) additional bonding among the surfaces and sides of the electronic component surface, because a large amount of the melted thermal interface material flows out of the interface between the heat sink and the electronic component surface and fills up the void around the electronic component surface; and e) bonding enhancement that is at least 100% greater than the bonding enhancement constituent of a heat sink coupled to an electronic component surface without a thermal interface material comprising a PCM—the “bare die” arrangement.

The contemplated thermal interface component can be provided as a dispensable paste to be applied by dispensing methods (such as screen printing, stencil printing, or automated dispensing) and then cured as desired. It can also be provided as a film or sheet for pre-application on interface surfaces, such as heat sinks. It can further be provided and produced as a soft gel or liquid that can be applied to surfaces by any suitable dispensing method, such as screen-printing or ink jet printing. Even further, the thermal interface component can be provided as a tape that can be applied directly to interface surfaces or electronic components.

Thermal interface materials and related layers can be laid down in any suitable thickness, depending on the needs of the electronic component, and the vendor as long as the thermal interface component is able to sufficiently perform the task of dissipating some or all of the heat generated from the surrounding electronic component. Contemplated thicknesses comprise a thickness of at least about 0.100 mm. In some embodiments, contemplated thicknesses comprise thicknesses in the range of about 0.100 mm to about 0.400 mm. In some embodiments, contemplated thicknesses of thermal interface materials are within the range of about 0.120 mm to about 0.300 mm. In other embodiments, contemplated thicknesses of thermal interface materials are within the range of about 0.125 mm to about 0.260 mm.

Methods of forming a layered electronic component include: a) providing a heat-generating component, usually contemplated as an electronic component surface; b) providing at least one thermal interface material, such as those described herein, wherein the thermal interface material is directly deposited onto the electronic component surface; c) providing a heat sink component having a top surface and a bottom surface; d) depositing, applying or coating the at least one thermal interface material onto at least part of at least one of the surfaces of the heat sink component, and e) bringing the surface of the heat sink component with the thermal interface material into contact with the heat generating device, which in some contemplated embodiments comprises the electronic component surface.

Contemplated methods of forming an electronic component include: a) providing a heat-generating component surface; b) providing at least one thermal interface material, wherein the thermal interface material is directly deposited onto the electronic component surface; c) providing a heat sink component having a top surface and a bottom surface; d) depositing, applying or coating the at least one thermal interface material onto at least part of at least one of the surfaces of the heat sink component, and e) coupling the surface of the heat sink component with the thermal interface material layer with the heat generating device to produce the electronic component.

Contemplated thermal interface materials, along with layered thermal interface materials and components may then be applied to a substrate, another surface, or another layered material. The electronic component may comprise, for example, a thermal interface material, a substrate layer and an additional layer. Substrates contemplated herein may comprise any desirable substantially solid material. Particularly desirable substrate layers would comprise films, glass, ceramic, plastic, metal or coated metal, or composite material. In preferred embodiments, the substrate comprises a silicon or germanium arsenide die or wafer surface, a packaging surface, such as found in a copper, silver, nickel or gold plated leadframe, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimide. The “substrate” may even be defined as another polymer material when considering cohesive interfaces. In more preferred embodiments, the substrate comprises a material common in the packaging and circuit board industries such as silicon, copper, glass, and another polymer.

Additional layers of material may be coupled to the thermal interface materials or layered interface materials in order to continue building a layered component or printed circuit board. It is contemplated that the additional layers will comprise materials similar to those already described herein, including metals, metal alloys, composite materials, polymers, monomers, organic compounds, inorganic compounds, organometallic compounds, resins, adhesives and optical wave-guide materials.

Applications of the contemplated thermal solutions, IC packages, thermal interface components, layered interface materials and heat spreader components described herein comprise incorporating the materials and/or components into another layered material, an electronic component or a finished electronic product. Electronic components, as contemplated herein, are generally thought to comprise any layered component that can be utilized in an electronic-based product. Contemplated electronic components comprise circuit boards, chip packaging, separator sheets, dielectric components of circuit boards, printed-wiring boards, and other components of circuit boards, such as capacitors, inductors, and resistors.

It is contemplated that the addition of the thermal interface materials described herein measurably increases the bonding of the electronic component over a reference component. This concept can be understood by considering a reference electronic component that comprises an electronic component surface and a heat sink. The two are coupled in a “bare die” arrangement without the use of a phase change material, such as those described herein. These reference electronic components comprise a neutral or zero bonding enhancement constituent. In contemplated electronic components comprising a thermal interface material layer, there is an increase in the bonding enhancement constituent. In some embodiments, the bonding enhancement constituent of the electronic component is at least 100% greater than the bonding enhancement constituent of the reference electronic component. In other embodiments, the bonding enhancement constituent of the electronic component is at least 200% greater than the bonding enhancement constituent of the reference electronic component. In yet other embodiments, the bonding enhancement constituent of the electronic component is at least 300% greater than the bonding enhancement constituent of the reference electronic component.

### EXAMPLES

### Example 1

### General Method of Preparing Contemplated Electronic Component

In forming a contemplated electronic component, a piece of PCM preformed pad with required/desired dimension and thickness may be used. The pad dimension should be equal or larger than the die size, in order to provide protection to the die before phase change.

The pad can be applied on the die (fully cover the die at the center) or applied to the heat sink surface, which will be contacting the die. Then assemble and/or couple the heat sink onto the die.

If further bonding is desired, a thicker pad or a second piece of the pad may be applied. In embodiments where screen printing is utilized, the printed material should be printed on the heat sink bottom surface to form a foot print as a pad. The minimum thickness must be achieved during the printing.

### Example 2

### Cantilever Test of Thermal Interface Materials Comprising Phase Change Materials

A cantilever test, which is designed to investigate the effect of the thickness of the thermal interface material when an unbalanced force is applied, was performed on electronic components comprising both TIM PCM pads and screen printed layers at various thicknesses.

In the first phase, the testing was carried out with two types of heat sinks which are with the same footprint. The PCM45F applications were 10 mils pads and screen printed layers of 5 mils and 10 mils thickness applied onto the heat sink surface with application area of 15×15 mm². The die surface of the testing vehicles is 12×12 mm². A 100° C. hot plate temperature and a 70° C. oven were used for curing both with and without a load at elevated temperatures.

In the first test, the heat sink was cured on the die without an external load. After curing, the bond line thickness (BLT) was measured at 10 mils with no dripping. The breaking force was measured at 1.72 kgf.

In the second test, the heat sink was cured on the die with 10 pounds of force for 1-2 seconds. After curing the BLT of the PCM was 1.5 to 2 mils, and the breaking force was measured at 2.2 kgf. It was observed that under moderate pressure, the excess material squeezed out of the interface and settled around the die. The material formed an extra bonding area between the substrate and the heat sink. This additional material provided additional bonding strength for these applications. In addition, the heat transfer was enhanced both from the die to the heat sink and the substrate to the heat sink.

In following testing, PCM45F pads and PCM45F screen printed layers were repeatedly tested. Each PCM embodiment was cured at 70° C. convection baking for 30 minutes. However, due to the pliable substrate of the testing vehicles, the breaking force measurement was with very large variation. The first phase test results are shown in Table 1:

| PCM | | | | |
|---|---|---|---|---|
| Application/ | | | | |
| thickness | Heat | Die | Curing Temp. and | Breaking |
| (mil) | Sink | (mm²) | Load (° C./Lbs/min) | Force (kgf) |
| Pad/10 | Type 1 | 12 × 12 | Hot plate, 100/0/30 | 1.72 |
| Pad/10 | Type 1 | 12 × 12 | Hot plate, 100/10/30 | 2.20 |
| Pad/10 | Type 1 | 12 × 12 | Oven, 70/10/30 | 1.49 |
| Pad/10 | Type 1 | 12 × 12 | Oven, 70/10/30 | 0.88 |
| Pad/10 | Type 1 | 12 × 12 | Oven, 70/10/30 | 1.54 |
| Pad/10 | Type 1 | 12 × 12 | Oven, 70/10/30 | 0.92 |
| SP/10 | Type 1 | 12 × 12 | Oven, 70/10/30 | 1.00 |
| SP/10 | Type 1 | 12 × 12 | Oven, 70/10/30 | 0.69 |
| SP/10 | Type 2 | 12 × 12 | Oven, 70/10/30 | 2.33 |
| SP/10 | Type 2 | 12 × 12 | Oven, 70/10/30 | 2.66 |
| SP/5 | Type 1 | 12 × 12 | Oven, 70/10/30 | 0.36 |
| SP/5 | Type 1 | 12 × 12 | Oven, 70/10/30 | 1.52 |
| SP/5 | Type 1 | 12 × 12 | Oven, 70/10/30 | 1.13 |
| SP/5 | Type 1 | 12 × 12 | Oven, 70/10/30 | 1.06 |
| SP/5 | Type 1 | 12 × 12 | Oven, 70/10/30 | 0.32 |
| SP/5 | Type 2 | 12 × 12 | Oven, 70/10/30 | 0.78 |
| SP/5 | Type 2 | 12 × 12 | Oven, 70/10/30 | 2.33 |

### Example 3

### Cantilever Test of Thermal Interface Materials Comprising Phase Change Materials

To reduce the uncertainty of the test result, dummy testing vehicles with aluminum substrate were applied for another set of cantilever tests, which was designed to investigate the effect of the thickness of the thermal interface material when an unbalanced force is applied. The tests were performed on electronic components comprising TIM PCM pads.

The PCM145F applications were utilized on heat sinks' surfaces. The PCM45F pad was 10 mils thick and 15×15 mm² in size. The PCM45F screen printed layers were with thickness of 2 mils, 5 mils, and 9 mils. The silicon chips on the dummy testing vehicles were of 12.7×12.7 mm² in size and 500 μm thick, A 70° C. oven temperature was used for curing the material. A 10 pound load was utilized during the curing at the elevated temperatures.

It was determined that excess PCM45F squeezes out to form extra bonding areas between the substrates/dies and the heat sinks. The experimental measurement demonstrated that a thicker pad/printing produced better bonding strength and accepted a larger force in the cantilever test before breaking. For example, the 10 mils pad withstood approximately 3.7 kgf (σ=0.63 kgf). The 9 mils pad withstood approximately 3.33 kgf (σ=0.63 kgf). The 5 mils pad withstood approximately 2.82 kgf (σ=0.55 kgf). The 2 mils pad withstood approximately 1.28 kgf (σ=0.47 kgf) In each of these measurements, the force was averaged from more than twenty (20) screen printed samples for each thickness FIG. 3 shows a summary of these experiments plotting application thickness in millimeters versus breaking force (kgf).

Thus, specific embodiments and applications of electronic packaging and heat sink bonding enhancements, methods of production and uses thereof have been disclosed. It should be apparent, however, to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. An electronic component, comprising:
a heat generating component surface;
a heat sink comprising a top surface and a bottom surface; and
a thermal interface material comprising a phase change material, wherein the heat generating component surface is coupled to the bottom surface of the heat sink by the thermal interface material.

2. The component of claim 1, wherein the heat generating component surface comprises an electronic component surface.

3. The component of claim 2, wherein the electronic component surface comprises silicon, silicon oxide, PCB board material, a ceramic material, aluminum, copper, an anodized surface, a painted surface or a combination thereof.

4. The component of claim 1, wherein the phase change material has a melting point in the range of about 20° C. to 145° C.

5. The component of claim 1, wherein the phase change material has a melting point in the range of about 45° C. to 60° C.

6. The component of claim 1, wherein the thermal interface material comprises a thickness of at least about 0.100 mm prior to a phase change of the phase change material.

7. The component of claim 1, wherein the thermal interface material comprises a thickness of at least about 0.175 mm prior to a phase change of the phase change material.

8. The component of claim 1, wherein the thermal interface material comprises a thickness of at least about 0.250 mm prior to a phase change of the phase change material.

9. The component of claim 1, wherein the thermal interface material comprises PCM45F, PCM45FSP or a combination thereof.

10. The component of claim 1, wherein the electronic component comprises a bonding enhancement constituent.

11. The component of claim 9, wherein the bonding enhancement constituent of the electronic component is at least 100% greater than the bonding enhancement constituent of an electronic component consisting essentially of an electronic component surface and a heat sink.

12. The component of claim 9, wherein the bonding enhancement constituent of the electronic component is at least 200% greater than the bonding enhancement constituent of an electronic component consisting essentially of an electronic component surface and a heat sink.

13. The component of claim 9, wherein the bonding enhancement constituent of the electronic component is at least 300% greater than the bonding enhancement constituent of an electronic component consisting essentially of an electronic component surface and a heat sink.

14. The component of claim 1, wherein the thermal interface material further comprises at least one high conductivity filler, at least one solder material or a combination thereof.

15. A method of forming an electronic component, comprising:
providing a heat-generating component surface;
providing at least one thermal interface material;
providing a heat sink component having a top surface and a bottom surface;
depositing the at least one thermal interface material onto at least part of at least one of the surfaces of the heat sink component, and
coupling the surface of the heat sink component with the thermal interface material layer with the heat generating component to produce the electronic component.

16. The method of claim 15, wherein the at least one thermal interface material comprises at least one phase change material.

17. The method of claim 16, further comprising activating the heat-generating component surface such that at least part of the phase change material changes phase.

18. The method of claim 15, wherein the heat generating component surface comprises an electronic component surface.

19. The method of claim 18, wherein the electronic component surface comprises silicon, silicon oxide, PCB board material, a ceramic material, aluminum, copper, an anodized surface, a painted surface or a combination thereof.

20. The method of claim 16, wherein the phase change material has a melting point in the range of about 20° C. to 145° C.
